(19) United States
(12) Patent Application Publication
(10) Pub. No.: US 2010/0134978 A1
(43) Pub. Date: Jun. 3, 2010

(54) Cooling fan housing structrue

(75) Inventor: Sheng-Huang Lin, Sinjhuang City (TW)

Correspondence Address: NIKOLAI & MERSEREAU, P.A., 900 SECOND AVENUE SOUTH, SUITE 820, MINNEAPOLIS, MN, 55402, US

(73) Assignee: Asia Vital Components Co., Ltd., Sinjhuang City (TW)

(21) Appl. No.: 12/319,999

(22) Filed: Jan. 14, 2009

(30) Foreign Application Priority Data
Dec. 1, 2008 (TW) 097221505

(51) Int. Cl. H05K 7/20

(52) U.S. Cl. 361/697

(57) ABSTRACT

A cooling fan housing structure for connecting to a heat sink includes a boosting portion, a top face, and an enclosing portion. The top face is outward extended from an end of the boosting portion, and the enclosing portion is extended from an end of the top face farther away from the boosting portion in a vertical direction opposite to the boosting portion. The top face and the enclosing portion together cover one side of the heat sink. The top face includes at least one projected element, and the heat sink includes at least one heat-absorbing portion and at least one heat-dissipating portion defining at least one heat-dissipating flow passage. By inserting and holding the projected element in the heat-dissipating flow passage, the cooling fan housing structure can be quickly and stably connected to the heat sink at reduced time and labor and manufacturing cost.

### FIELD OF THE INVENTION

The present invention relates to a cooling fan housing structure and a thermal module consisting of such cooling fan housing structure, and more particularly to a cooling fan housing structure that can be quickly and stably assembled to a heat sink to provide a thermal module.

### BACKGROUND OF THE INVENTION

When an electronic device operates, the internal electronic components thereof would produce heat. Therefore, a heat-dissipating unit is required to help in increasing the heat-dissipation efficiency of the electronic device to avoid burnout or other damages of the electronic components due to overheating. The heat-dissipating unit is mainly a radiating fin assembly or a heat sink. Since the above-described heat-dissipating unit alone can only achieve limited effect in dissipating the heat produced by the electronic components, at least one cooling fan is associated with the heat-dissipating unit, so that the cooling fan produces and forces airflows through the heat-dissipating unit to achieve upgraded overall heat dissipation efficiency thereof. Conventionally, the cooling fan is associated with the heat-dissipating unit mainly by directly fixing the cooling fan to the radiating fins of the heat-dissipating unit using fastening elements, such as screws or bolts. By doing this, the radiating fins of the heat-dissipating unit are subject to deformation or even damage and the space between any two adjacent radiating fins is reduced due to the pressure from the fastening elements. The deformed or damaged radiating fins would result in narrowed flow passages and accordingly wind resistance to adversely affect the heat dissipation. Alternatively, the cooling fan is fixed to the heat-dissipating unit via a separate mounting rack in an attempt to solve the problem of deformed radiating fins and narrowed flow passages. To do so, additional screws or other types of fastening elements are needed to stably and firmly fix the cooling fan and the mounting rack to the heat-dissipating unit.

Please refer to FIG. 1 that is an exploded perspective view of a conventional thermal module 1. As shown, the thermal module 1 includes a cooling fan 11, a mounting rack 12, and a heat sink 13. The cooling fan 11 is provided at four corners with a through hole 111 each. A plurality of screws 14 is threaded through the through holes 111 to lock the cooling fan 11 to the mounting rack 12. The mounting rack 12 is provided at two opposite lower lateral sides with a retaining arm 121 each. The retaining arms 121 can be engaged with notches 131 formed on two lateral sides of the heat sink 13, so as to fixedly hold the cooling fan 11 to the heat sink 13. While the thermal module 1 has the cooling fan 11 connected to the heat sink 13 via the mounting rack 12, a lot of labor and time is needed to do such assembly and thereby increases the manufacturing cost of the thermal module 1. Moreover, the cooling fan 11 vibrates when it operates, bringing the whole thermal module 1 to produce noise or vibration. In brief, the conventional thermal module with a cooling fan has the following disadvantages: (1) having complicated structure; (2) requiring a lot of time and labor to assemble; (3) having increased manufacturing cost; and (4) easy to produce vibration.

It is therefore tried by the inventor to develop an improved cooling fan housing structure and a thermal module with such cooling fan housing structure to overcome the drawbacks existed in the prior art cooling fan housing structures and thermal modules.

### SUMMARY OF THE INVENTION

A primary object of the present invention is to provide a cooling fan housing structure that enables a cooling fan to be quickly assembled to a heat sink.

Another object of the present invention is to provide a thermal module that includes a cooling fan housing structure that enables a cooling fan and a heat sink to be quickly assembled together.

A further object of the present invention is to provide a cooling fan housing structure that enables a thermal module to be manufactured at reduced cost.

To achieve the above and other objects, the cooling fan housing structure according to the present invention includes a boosting portion, a top face, and an enclosing portion. The top face is outward extended from an end of the boosting portion, and the enclosing portion is extended from an end of the top face farther away from the boosting portion in a vertical direction opposite to the boosting portion. The top face and the enclosing portion together cover one side of the heat sink. The top face can include at least one projected element that can be inserted into the heat sink.

And, to achieve the above and other objects, the thermal module according to the present invention includes a heat sink and a cooling fan housing structure. The heat sink includes at least one heat-absorbing portion and at least one heat-dissipating portion having a plurality of radiating fins. The cooling fan housing structure includes a boosting portion, a top face, and an enclosing portion. The top face and the enclosing portion together cover one side of the heat sink. The top face can include at least one projected element. When the top face and the enclosing portion together cover one side of the heat sink, the projected element is correspondingly inserted into a heat-dissipating flow passage formed among the radiating fins of the heat sink to quickly and stably connect the cooling fan housing structure to the heat sink. Thus, the thermal module of the present invention can be manufactured at reduced labor and time costs.

In brief, the present invention provides the following advantages: (1) having simple structure; (2) enabling quick assembling; (3) having reduced manufacturing cost; (4) requiring only reduced assembling labor and time; and (5) ensuring stable assembling thereof without the risk of producing vibration.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is an exploded perspective view of a conventional thermal module;

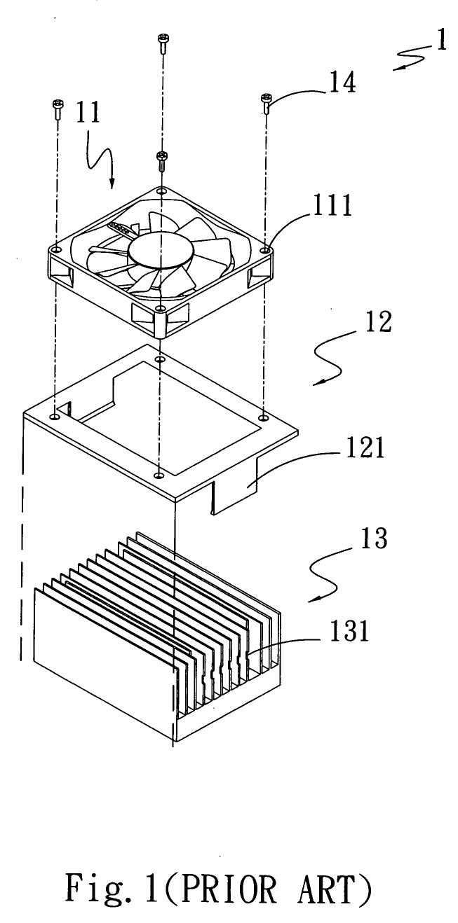

FIG. 2 is an exploded perspective view of a thermal module with a cooling fan housing structure according to a preferred embodiment of the present invention;

FIG. 3 is an assembled view of FIG. 2;

FIG. 4 is a cutaway view of FIG. 3 showing an internal structure of the thermal module of the present invention;

FIG. 4A is an enlarged view of the circled area 4A in FIG. 4;

FIG. 5 is an assembled sectional view of the thermal module of the present invention;

FIG. 5A is an enlarged view of the circled area 5A in FIG. 5;

FIG. 6 is an assembled sectional view of a thermal module according to another embodiment of the present invention;

FIG. 6A is an enlarged view of the circled area 6A in FIG. 6;

FIG. 7 is an exploded sectional view of the thermal module according to the preferred embodiment of the present invention; and

FIG. 8 is an exploded perspective view showing a cooling fan housing structure according to a preferred embodiment of the present invention with a fan blade assembly separated therefrom.

### DETAILED DESCRIPTION OF THE PREFERRED EMBODIMENTS

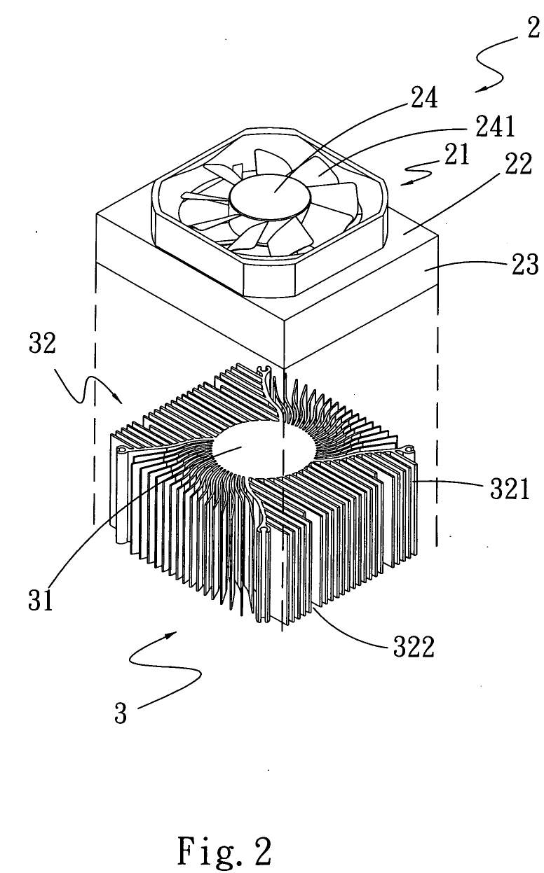

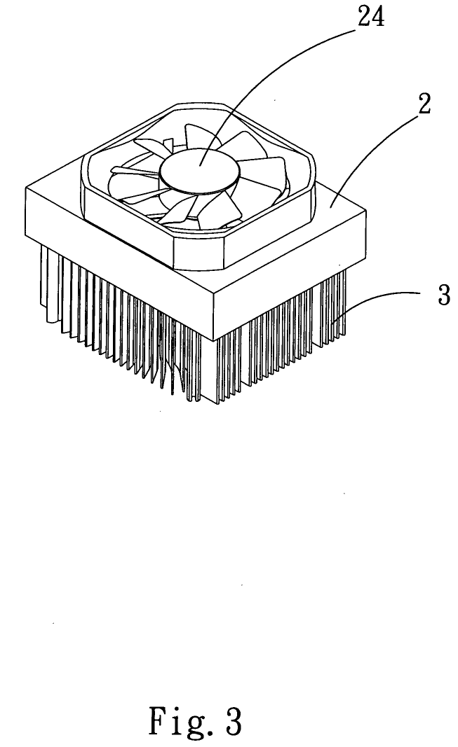

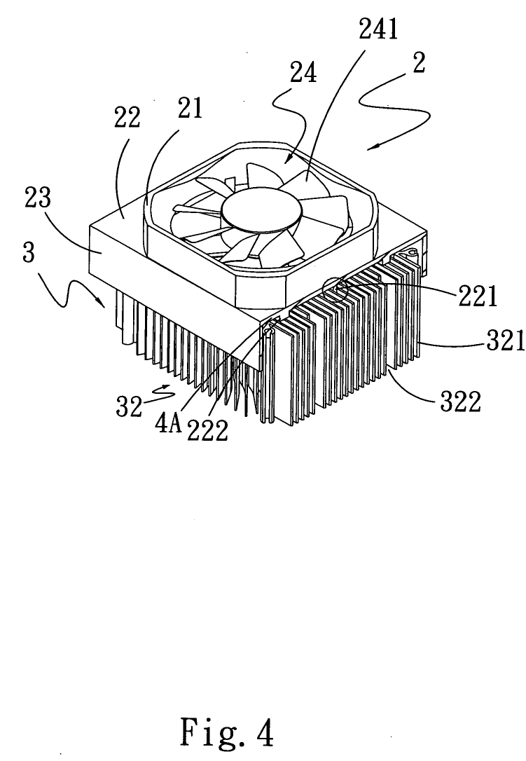

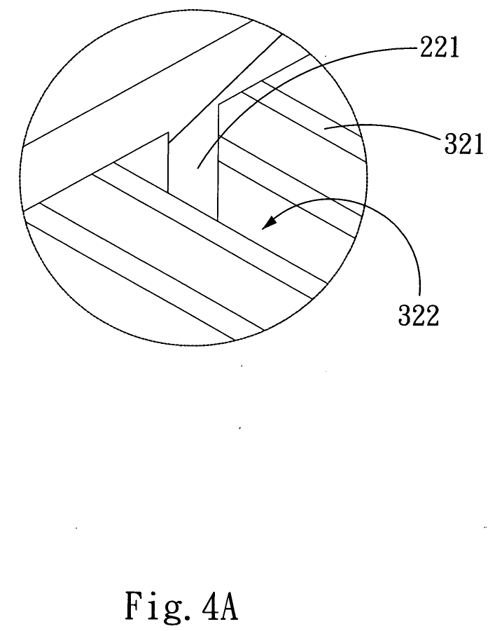

Please refer to FIGS. 2, 3, 4, 4A, 5, 5A, 6, 6A, 7 and 8. A cooling fan housing structure 2 according to a preferred embodiment of the present invention can be assembled to a heat sink 3. The cooling fan housing structure 2 includes a boosting portion 21, a top face 22, and an enclosing portion 23. The top face 22 is outward extended from an end of the boosting portion 21. The enclosing portion 23 is extended from an end of the top face 22 farther away from the boosting portion 21 in a vertical direction opposite to the boosting portion 21. The top face 22 and the enclosing portion 23 together cover one side of the heat sink 3. The top face 22 includes at least one projected element 221 for inserting into a heat-dissipating flow passage 322 formed between two adjacent radiating fins 321 of the heat sink 3, as can be seen from FIGS. 4 and 4A.

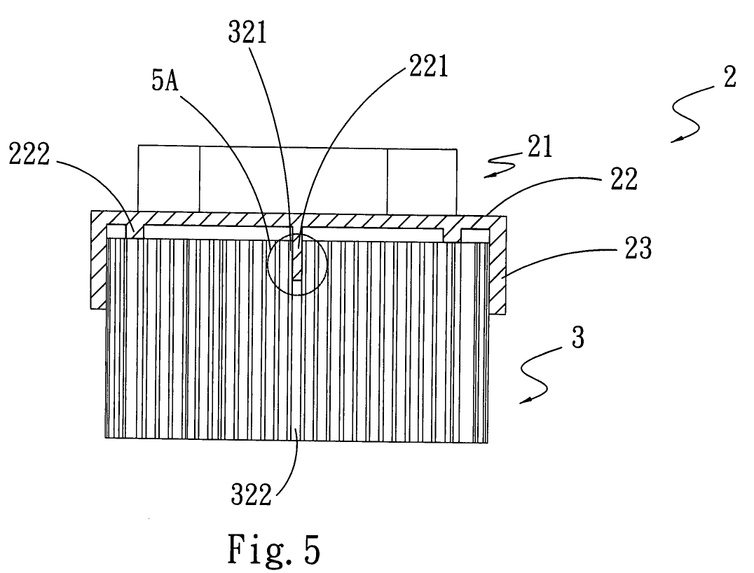

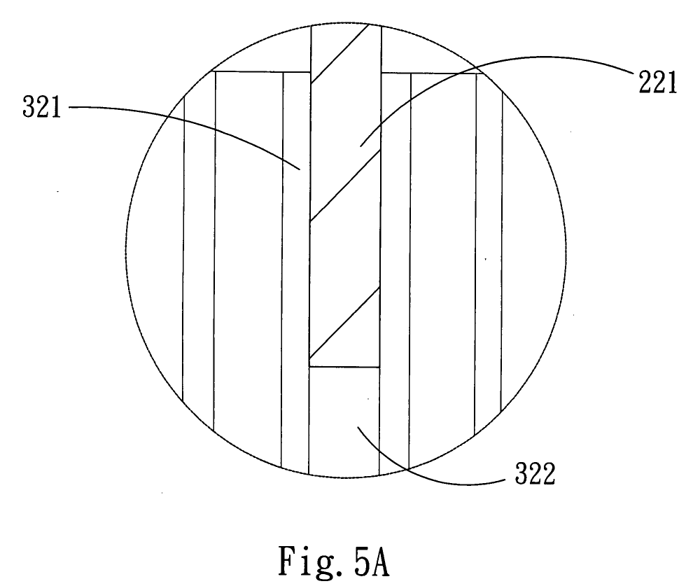

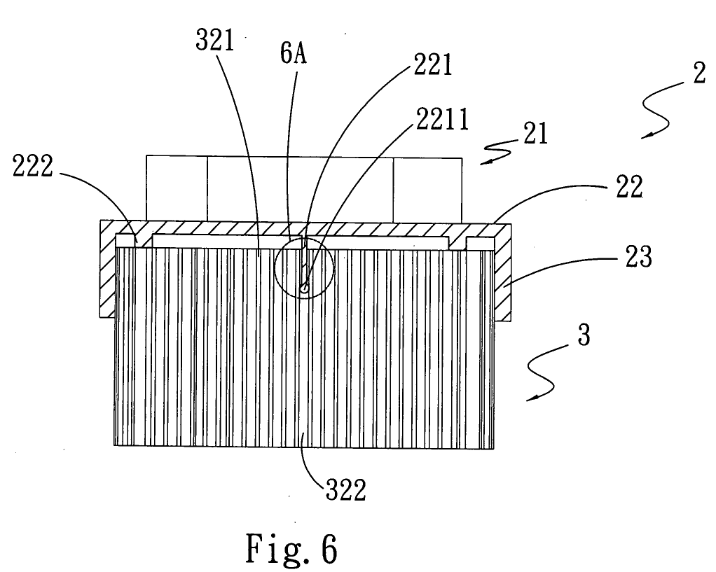

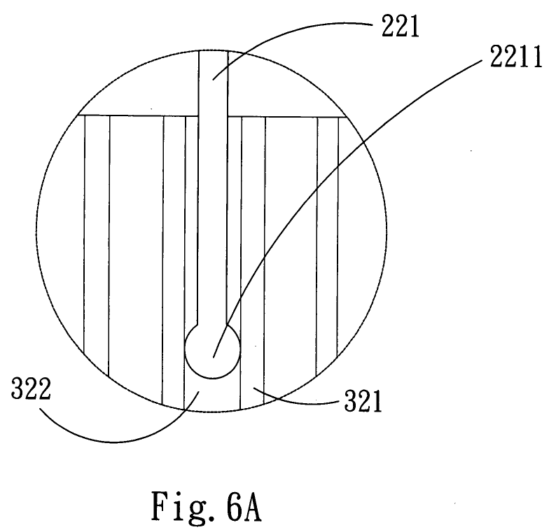

The projected element 221 further include an extended free end 2211, which can be tightly fitted and held in the heat-dissipating flow passage 322 between the adjacent radiating fins 321. In the embodiment illustrated in FIGS. 5 and 5A, the extended free end 2211 of the projected element 221 is square in shape, and in another embodiment illustrated in FIGS. 6 and 6A, the extended free end 2211 is spherical in shape. However, the extended free end 2211 of the projected element 221 can also be selected from other shapes, such as in the form of an expanded head (not shown) or in the form of a claw (not shown).

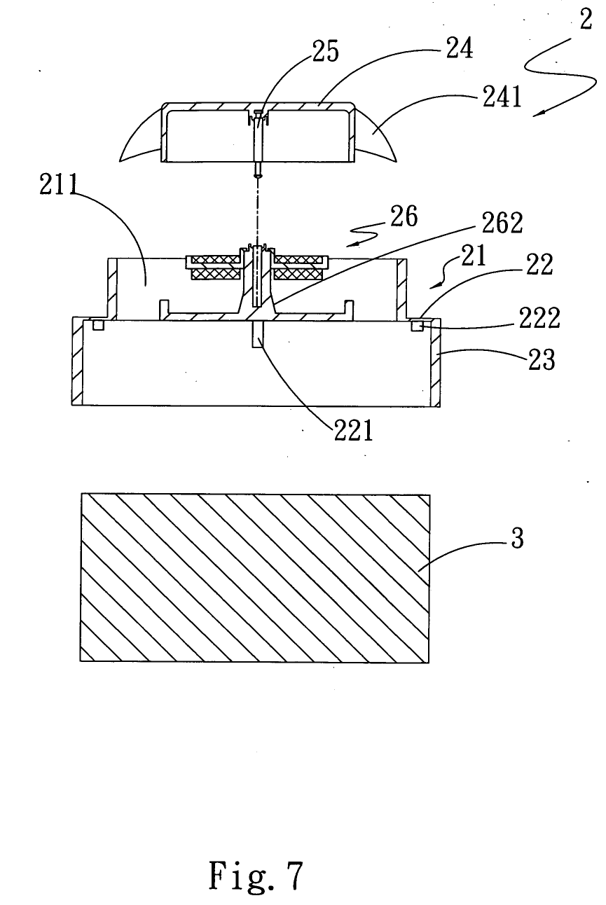

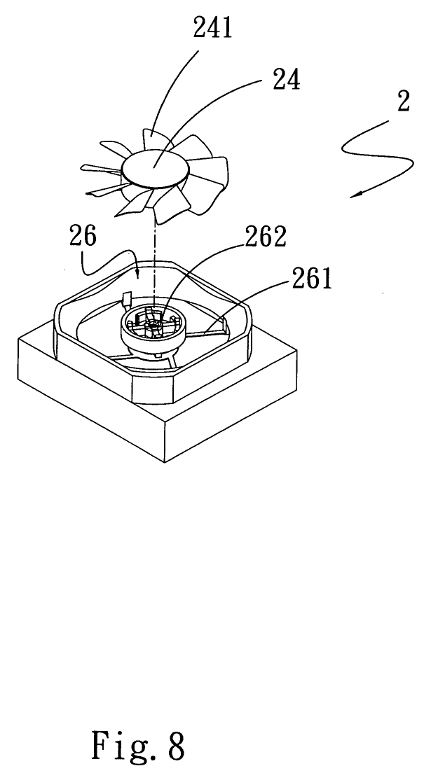

Please refer to FIGS. 7 and 8. The cooling fan housing structure 2 further includes a supporting portion 26, which includes a plurality of connecting bars 261 and a cylindrical spindle seat 262. The connecting bars 261 each have a radially inner end connected to the cylindrical spindle seat 262, and a radially outer end connected to the top face 22. The cylindrical spindle seat 262 rotatably supports a fan blade assembly 24 thereon. The fan blade assembly 24 includes a spindle 25 and a plurality of blades 241. The spindle 25 is connected at an end to the fan blade assembly 24. The fan blade assembly 24 is located in the boosting portion 21 with another opposite end of the spindle 25 inserted in the cylindrical spindle seat 262 of the supporting portion 26.

The top face 22 is horizontally outward extended from an end of the boosting portion 21. The enclosing portion 23 is extended from an end of the top face 22 farther away from the boosting portion 21 in a vertical direction opposite to the boosting portion 21. The top face 22 further includes at least one stopper 222, and at least one side of the heat sink 3 is pressed against the stopper 222. The boosting portion 21 defines a flow passage 211, which communicates with the supporting portion 26 and the enclosing portion 23.

Please refer to FIGS. 4, 4A, 5, 5A, 6, 6A, 7, and 8. As shown, a thermal module according to a preferred embodiment of the present invention includes a heat sink 3 and a cooling fan housing structure 2. The heat sink 3 includes at least one heat-absorbing portion 31 and at least one heat-dissipating portion 32. The heat-dissipating portion 32 includes a plurality of radiating fins 321, which are radially outward extended from a periphery of the heat-absorbing portion 31. At least one heat-dissipating flow passage 322 is formed among the radiating fins 321. The cooling fan housing structure 2 includes a boosting portion 21, a top face, 22, and an enclosing portion 23. The top face 22 and the enclosing portion 23 together cover one side of the heat sink 3. The top face 22 includes at least one projected element 221. When the top face 22 and the enclosing portion 23 together cover one side of the heat sink 3, the at least one projected element 221 is correspondingly inserted into and held in the heat-dissipating flow passage 322 formed among the radiating fins 321 of the heat sink 3, as can be seen from FIGS. 4 and 4A.

The projected element 221 further include an extended free end 2211, which can be tightly fitted and held in the heat-dissipating flow passage 322 formed among the radiating fins 321. In the embodiment illustrated in FIGS. 5 and 5A, the extended free end 2211 of the projected element 221 is square in shape, and in another embodiment illustrated in FIGS. 6 and 6A, the extended free end 2211 is spherical in shape. However, the extended free end 2211 of the projected element 221 can also be selected from other shapes, such as in the form of an expanded head (not shown) or in the form of a claw (not shown).

The top face 22 of the cooling fan housing structure 2 is horizontally outward extended from an end of the boosting portion 21, and the enclosing portion 23 is extended from an end of the top face 22 farther away from the boosting portion 21 in a vertical direction opposite to the boosting portion 21. The top face 22 is further provided with at least one stopper 222, and at least one side of the heat sink 3 is pressed against the at least one stopper 222.

The cooling fan housing structure 2 further includes a supporting portion 26, which includes a plurality of connecting bars 261 and a cylindrical spindle seat 262. The connecting bars 261 each have a radially inner end connected to the cylindrical spindle seat 262, and a radially outer end connected to the top face 22. The cylindrical spindle seat 262 rotatably supports a fan blade assembly 24 thereon. The fan blade assembly 24 includes a spindle 25 and a plurality of blades 241. The spindle 25 is connected at an end to the fan blade assembly 24. The fan blade assembly 24 is located in the boosting portion 21 with another opposite end of the spindle 25 inserted in the cylindrical spindle seat 262 of the supporting portion 26. The boosting portion 21 defines a flow passage 211, which communicates with the supporting portion 26 and the enclosing portion 23.

The present invention has been described with some preferred embodiments thereof and it is understood that many changes and modifications in the described embodiments can be carried out without departing from the scope and the spirit of the invention. For example, the shapes or the arrangements of the components thereof can be changed. All equivalent functions and effects derived from the changes, modifications and applications of the described preferred embodiment should be included in the scope of the present invention. Therefore, the scope and the spirit of the present invention is intended to be limited only by the appended claims.

1. A cooling fan housing structure for connecting to a heat sink, comprising:
a boosting portion, a top face, and an enclosing portion;
the top face being extended from an end of the boosting portion, and the enclosing portion being connected to another end of the top face opposite to the boosting portion; and
the top face and the enclosing portion together covering one side of the heat sink; the top face having at least one projected element extending from the bottom of the top face, and the at least one projected element capable of being inserted into a heat-dissipating flow passage of the heat sink.

2. The cooling fan housing structure as claimed in claim 1, further comprising a supporting portion; the supporting portion including a plurality of connecting bars and a cylindrical spindle seat, and each of the connecting bars being connected at a radially inner end to the cylindrical spindle seat and at a radially outer end to the top face.

3. The cooling fan housing structure as claimed in claim 2, wherein the cylindrical spindle seat rotatably supports a fan blade assembly thereon; and the fan blade assembly includes a spindle.

4. The cooling fan housing structure as claimed in claim 1, wherein the top face further includes at least one stopper, and the heat sink has at least one side pressed against the at least one stopper.

5. The cooling fan housing structure as claimed in claim 3, wherein the spindle is inserted in the cylindrical spindle seat.

6. The cooling fan housing structure as claimed in claim 2, wherein the boosting portion defines a flow passage, and the flow passage communicates with the supporting portion and the enclosing portion.

7. The cooling fan housing structure as claimed in claim 3, wherein the fan blade assembly includes a plurality of blades.

8. The cooling fan housing structure as claimed in claim 1, wherein the top face is horizontally outward extended from an end of the boosting portion, and the enclosing portion is extended from an end of the top face farther away from the boosting portion in a vertical direction opposite to the boosting portion.

9. The cooling fan housing structure as claimed in claim 1, wherein the projected element further has an extended free end, and the extended free end has a shape selected from the group consisting of an expanded head, a spherical shape, a square shape, and a claw shape.

10. A thermal module, comprising:
a heat sink including at least one heat-absorbing portion and at least one heat-dissipating portion; the heat-dissipating portion including a plurality of radiating fins, and at least one heat- dissipating flow passage being formed among the radiating fins; and
a cooling fan housing structure including a boosting portion, a top face, and an enclosing portion; the top face and the enclosing portion together covering one side of the heat sink; the top face having at least one projected element traversing across at least a portion of a bottom of the top face, such that when the top face and the enclosing portion together cover one side of the heat sink, the at least one projected element is correspondingly inserted into and held in the heat- dissipating flow passage formed among the radiating fins of the heat sink.

11. The thermal module as claimed in claim 10, wherein the cooling fan housing structure further includes a supporting portion; the supporting portion including a plurality of connecting bars and a cylindrical spindle seat; each of the connecting bars being connected at a radially inner end to the cylindrical spindle seat and a radially outer end to the top face.

12. The thermal module as claimed in claim 11, wherein the cylindrical spindle seat rotatably supports a fan blade assembly thereon, and the fan blade assembly further includes a spindle.

13. The thermal module as claimed in claim 10, wherein the top face further includes at least one stopper, and the heat sink has at least one side pressed against the at least one stopper.

14. The thermal module as claimed in claim 12, wherein the spindle is inserted in the cylindrical spindle seat.

15. The thermal module as claimed in claim 11, wherein the boosting portion defines a flow passage, and the flow passage communicates with the supporting portion and the enclosing portion.

16. The thermal module as claimed in claim 10, wherein the top face is horizontally outward extended from an end of the boosting portion, and the enclosing portion is extended from an end of the top face farther away from the boosting portion in a vertical direction opposite to the boosting portion.

17. The thermal module as claimed in claim 10, wherein the heat-dissipating portion of the heat sink is radially outward extended from a periphery of the heat- absorbing portion.

18. The thermal module as claimed in claim 10, wherein the projected element further has an extended free end, and the extended free end has a shape selected from the group consisting of an expanded head, a spherical shape, a square shape, and a claw shape.
